(19) United States
(12) Patent Application Publication
(10) Pub. No.: US 2012/0153980 A1
(43) Pub. Date: Jun. 21, 2012

(54) PROBE ASSEMBLY

(75) Inventors: KANG WU, Shenzhen City (CN); BO TIAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/978,532

(22) Filed: Dec. 24, 2010

(30) Foreign Application Priority Data
Dec. 21, 2010 (CN) 201010598874.3

(51) Int. Cl. G01R 1/067

(52) U.S. Cl. 324/755.01

(57) ABSTRACT

A probe assembly includes a transducer, a cable, and a probe. A cover of the cable is made of pliable metal material or a flexible metal conduit. Opposite ends of the cable are respectively coupled to the transducer and the probe.

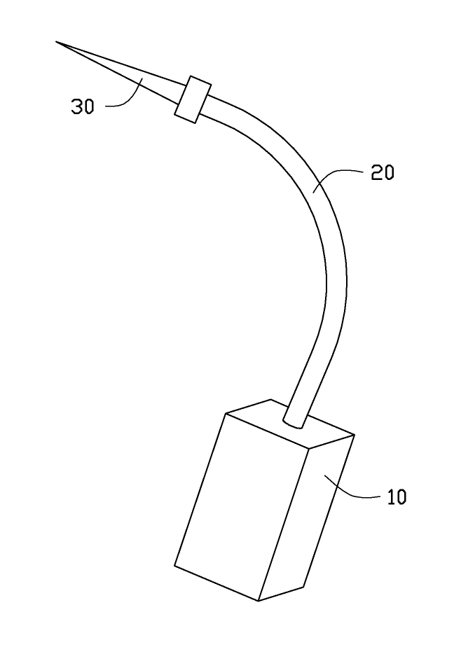

### BACKGROUND

1. Technical Field

The present disclosure relates to a probe assembly of an oscillograph.

2. Description of Related Art

Oscillographs are often used for testing circuit boards of electronic devices. However, probes of an oscillograph are generally connected to the oscillograph by cables that are too flexible to assist with holding the probes in place when contacted to part of the circuit board. As a result, the probes must be manually held in place, which is inconvenient.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments. Moreover, in the drawing, the view is schematic.

The FIGURE is an isometric view of an exemplary embodiment of a probe assembly of an oscillograph.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the FIGURE, an exemplary embodiment of an assembly of probe of an oscillograph (not shown) includes a transducer 10, a cable 20, and a tapered probe 30.

The transducer 10 is substantially rectangular, and electrically connected to the oscillograph.

The covering of the cable 20 is made of flexible metal material but still stiff enough that it can maintain a shape once bent to that shape until acted on by a force greater than the stiffness, such as what an operator could easily apply with their hands when positioning the cable 20. Opposite ends of the cable 20 are respectively coupled to the transducer 10 and the probe 30. In another embodiment, the covering can be made with a flexible metal conduit that can be shaped flexibly, yet able to maintain the shape.

In use, the cable 20 can be bent to a desired shape to help maintain the probe 30 in a fixed position relative to a probe point of a circuit board (not shown) to test a portion thereon.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A probe assembly comprising:
a transducer;
a probe; and
a cable connected between the transducer and the probe, wherein a cover of the cable is made of pliable metal material or a flexible metal conduit that can be shaped into a desired form and maintain that form until manually acted on to reshape the form.
